(19) United States
(12) Patent Application Publication
(10) Pub. No.: US 2008/0078326 A1
(43) Pub. Date: Apr. 3, 2008

(54) Pre-cleaning tool and semiconductor processing apparatus using the same

(75) Inventors: Kuo-Liang Sung, Hsinchu (TW); Wen-Sheng Wu, Hsinchu (TW); Victor Chen, Hsinchu (TW); Shuen-Liang Tseng, Hsinchu City (TW)

Correspondence Address: BIRCH STEWART KOLASCH & BIRCH, PO BOX 747, FALLS CHURCH, VA, 22040-0747, US

(73) Assignee: TAIWAN SEMICONDUCTOR MANUFACTURING CO., LTD., Hsin-Chu (TW)

(21) Appl. No.: 11/529,593

(22) Filed: Sep. 29, 2006

(51) Int. Cl. H01L 21/306; C23C 16/00

(52) U.S. Cl. 118/723 R; 156/345.1

(57) ABSTRACT

Pre-cleaning tools and semiconductor processing apparatuses using the same are provided. An exemplary pre-cleaning tool comprises a support unit for supporting a substrate, a dome unit for substantially covering the support unit, a first RF unit connected to the support unit and a second RF unit connected to the dome unit. The dome unit is partially ceramic bead-blasted at an inner surface thereof.

### BACKGROUND OF THE INVENTION

1. Field of the Invention

The invention relates to semiconductor processing, and in particular to a pre-cleaning tool and a semiconductor processing apparatus using the same.

2. Description of the Related Art

Current integrated circuits generally include various formations of multilevel metal structures that form a high-conductivity, thin-film network fabricated above the silicon surface to connect various active devices through specific electrical paths. During the formation of metal-to-metal and metal-to-silicon contact structures in this thin-film network, openings such as via openings and/or trench openings are etched in the dielectric layer that separates the substrate or underlying conductive thin film from the overlying conductive thin film. After openings for interconnect structures (lines and vias) have been etched through the dielectric, a diffusion barrier layer is commonly deposited over the dielectric to prevent intermixing or diffusion of interconnect material. A conductive material, such as copper, aluminum, or other metal, is then used to fill the opening and make a connection to the silicon substrate or underlying conductive thin film.

Sub-micron multilevel metallization is important for the next generation of very large scale integration (“VLSI”). Reliable formation of the multilevel interconnects is very important to the success of VLSI and to the continued effort to increase circuit density and quality on individual substrates and die. Chemical vapor deposition (CVD) and physical vapor deposition (PVD) techniques are conventionally used to conformably form a diffusion barrier layer into the contact holes, vias, trenches, or other patterns formed on the substrate. However, native oxides formed on the exposed portion of the previously formed conductive interconnects and other contaminants within a small feature typically result in voids by promoting uneven distribution of the depositing metal. The native oxide typically forms as a result of exposure of the exposed film layer/substrate to oxygen when moving substrates between processing chambers at atmospheric conditions, or when the small amount of oxygen remaining in a vacuum chamber contacts the wafer/film layer, or when a layer is contaminated by etching. Other contaminants can comprise sputtered material from an oxide over-etch, residual photoresist from a stripping process, leftover hydrocarbon or fluorinated hydrocarbon polymers from a previous oxide etch step, or redeposited material from a preclean sputter etch process. The native oxide and other contaminants create regions on the substrate which interfere with film formation, by creating regions where film deposition is stunted. Regions of increased growth merge and seal the small features before conformation deposition of the diffusion barrier layer.

The presence of native oxides and other contaminants can also increase via/contact resistance and reduce the electromigration resistance of small features. The contaminants can diffuse into the dielectric layer, the sublayer, or the sequentially deposited metal and alter the performance of devices which include the small features. Although contamination may be limited to a thin boundary region within the features, the thin boundary region is a substantial part of the small features. The acceptable level of contaminants in the features decreases as the features narrow.

In the prior art, an apparatus named “ENDURA” system capable of pre-cleaning a patterned structure with a plasma comprising a mixture of argon, helium and hydrogen is commercially available from Applied Materials, Inc., Santa Clara, Calif. The apparatus can be used to remove the native oxide and other contaminants before formation of the diffusion barrier. However, such plasma treatment may damage dielectric layers such as silicon oxide layers adjacent to an interconnect structure in practice, thereby sputtering some material near the top portion of the interconnect structure which adheres to an inner surface of the quartz dome of the apparatus. Thus, a particle source is formed in the pre-clean chamber and may peel off and fall on a patterned interconnect structure during a pre-clean process, thereby causing yield damage. In addition, sequentially filled conductive material such as copper may easily diffuse through dielectrics through damaged sidewalls of vias formed in dielectrics, destroying or compromising the integrity of the dielectric. This diffusion is especially true when using TEOS oxide, thermal oxide and some low-K dielectric materials when incorporating copper damascene process.

### BRIEF SUMMARY OF THE INVENTION

Therefore, a pre-cleaning tool avoiding the drawback described is called for, especially for copper damascene process incorporating low-K dielectric materials.

An exemplary pre-cleaning tool comprises a support unit for supporting a substrate, a dome unit for substantially covering the support unit, a first RF unit connected to the support unit and a second RF unit connected to the dome unit. The dome unit is partially ceramic bead-blasted at an inner surface thereof.

An exemplary semiconductor processing apparatus comprises a pre-clean unit and a process unit. The pre-clean unit comprises a load lock chamber for storing a substrate or a substrate cassette, the pre-cleaning tool disclosed and a first robot for transferring a substrate from and between the load lock chamber and the pre-cleaning tool. The process unit comprises a process chamber for film deposition and a second robot for transferring the substrate from and between the process chamber and the pre-cleaning tool.

A detailed description is given in the following embodiments with reference to the accompanying drawings.

### BRIEF DESCRIPTION OF THE DRAWINGS

The invention can be more fully understood by reading the subsequent detailed description and examples with references made to the accompanying drawings, wherein:

FIG. 1 is a schematic diagram showing a pre-cleaning tool of the invention;

FIG. 2 is a schematic view of an inner surface of a covering dome of the pre-clean chamber of FIG. 1, partially covered by ceramic bead-blasting;

FIG. 3 is a schematic top view of a cover ring of the plasma treatment chamber of FIG. 1, entirely covered by ceramic bead-blasting;

FIG. 4 is a daily particle chart showing particle monitoring results of a pre-cleaning tool while using or not using ceramic bead-blasting parts; and

FIG. 5 shows overall layout of a semiconductor process apparatus having a pre-cleaning tool of the invention.

### DETAILED DESCRIPTION OF THE INVENTION

The following description is of the best-contemplated mode of carrying out the invention. This description is made for the purpose of illustrating the general principles of the invention and should not be taken in a limiting sense. The scope of the invention is best determined by reference to the appended claims.

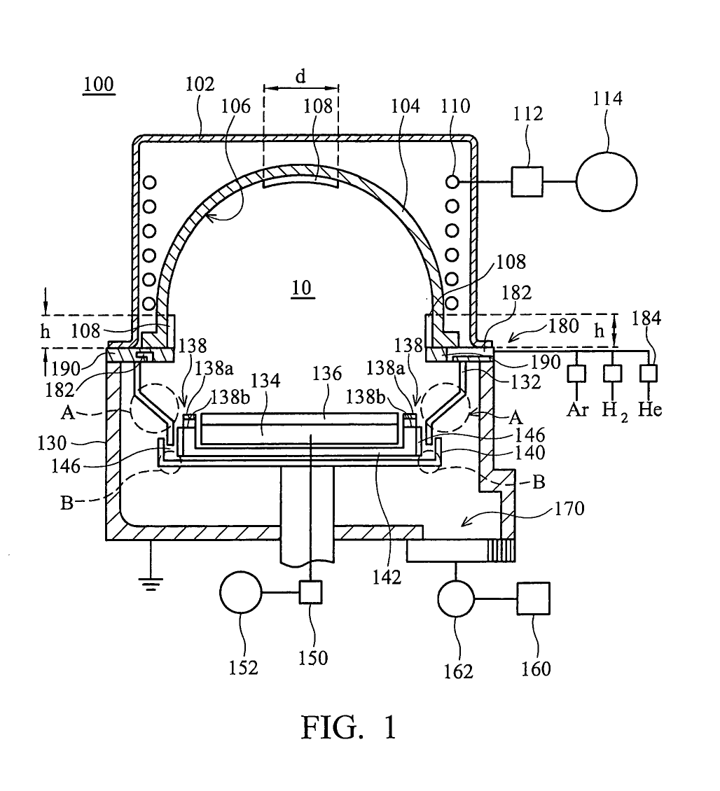

Referring to FIG. 1, a pre-cleaning tool 100 for conducting a dry pre-clean removing native oxide and other contaminates before formation of a diffusion barrier is shown schematically. The pre-cleaning tool 100 provides a dry plasma treatment and includes a vacuum chamber 10 enclosed by a base unit 130 and a dome unit 104. Preferably, the base unit 130 is metal such as stainless steel, aluminum or the like and the dome unit 104 is non-metal such as quartz or the like. An opening 170 in the base of the base unit 130 is connected to a throttle valve 162 and a turbo pump 160 controlling gas pressure inside the chamber 10. The throttle valve 162 is automated to allow servo control to a specific pressure. The dome unit 104 forms the top of the chamber 10 and is provided with a flange 190 about its circumference where it meets the top circumference of the sidewalls of base unit 130. A gas distribution system 180 is provided at the juncture of dome unit 104 and base unit 130. The top of the sidewall of the base unit 130 has a gas supply trench 182 embedded therein and from six to twelve evenly spaced (angularly) disposed channels extending from one or more gas sources intersect the channel to form a plurality of gas injection holes. The gas distribution system 180 supplies Ar, He, and H₂ gases which are typically metered by mass flow controllers 184. Hydrogen may also be supplied as a mixture with helium having about 5% hydrogen by volume for safe delivery of the hydrogen. However, a separate hydrogen line is still provided to attain hydrogen concentrations greater than 5% by volume. A conductive pedestal 134 formed of, for example, Al, which is arranged to hold a substrate or wafer (not shown), is disposed over a support unit 142 surrounding the sides and bottom thereof. An insulating layer 136 may be placed between the conductive pedestal 134 and the wafer (not shown). The support unit 142 is formed over a lower shield 140, comprising conductive materials such as aluminum. An upper shield 132 is formed and connected to the flange 190 disposed under the dome unit 104, pushing the lower shield 140 toward the upper shield 132. The support unit 142, the conductive pedestal 134, and the substrate or wafer held by the support unit 142 therefore reach a process position and provide a process space for pre-cleaning.

RF power from an RF source 152 is applied capacitively to the conductive pedestal 134. A RF match box 150 adjusts the chamber impedance to optimize power transfer between the power source 152 and the conductive pedestal 134. Typical RF frequencies are from about 2 MHz to about 60 MHz at power levels from about 10 W to about 500 W.

Additional power is inductively supplied to the plasma by energizing coils 110 wound exterior to the dome unit 104 and supported by a cover 102. An alternating axial electromagnetic field is produced in the chamber 10 interior to the winding of the coils 110. Generally, an RF frequency between 200 KHz and 16 MHz is employed. A 2 MHz frequency is common. An RF source 114 operating at this frequency is coupled to the coil 110 by matching network 112.

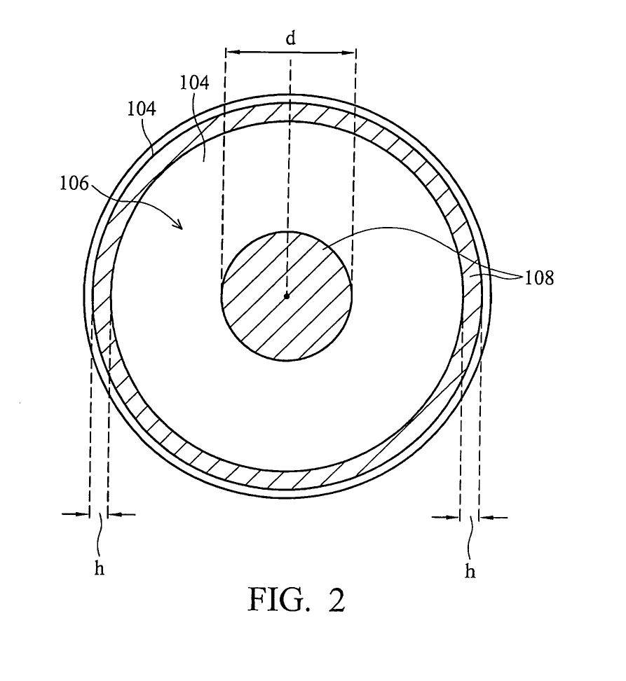

As shown in FIG. 1, for the purpose of preventing or reducing particles peeling off or falling down, the dome unit 104 is now partially ceramic bead-blasted at portions of the inner surface 106 thereof, illustrated as the ceramic bead-blasted regions 108 here. The ceramic bead-blasted regions 108 are mainly located at a top center portion and a bottom circumference thereof. The ceramic bead-blasted center portion of the dome unit 104 is formed within a circled region d having a diameter about 10˜18 cm from a center of the dome unit 104. FIG. 2 illustrates a top view from an inner surface of the dome unit 104, illustrating distributions of the ceramic bead-blasted regions 108. The ceramic bead-blasted regions may comprise aluminum oxide, calcium oxide, magnesium oxide, titanium oxide, zirconium oxide, or Teflon@. The ceramic bead-blasted bottom circumference of the dome unit 104 is formed as a strip region h about 3˜8 cm wide extending from a bottom surface toward the center of the dome unit. The ceramic bead-blasted regions as described above has a thickness of about 5˜30 μm.

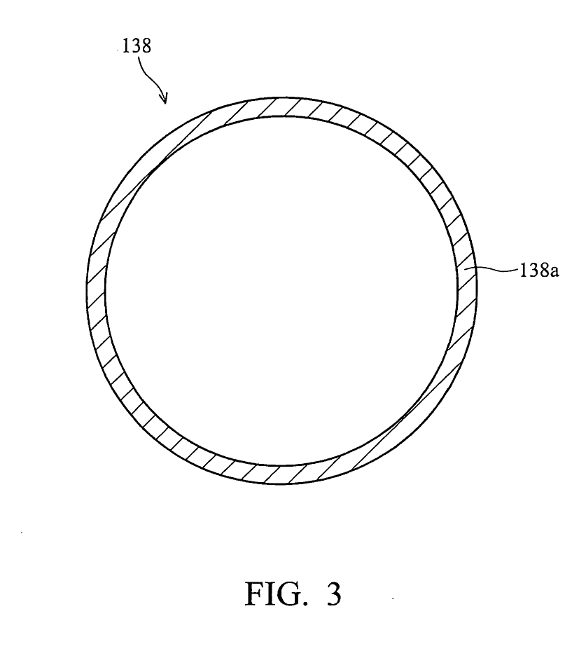

As shown in FIG. 1, for the purpose of preventing or reducing particles peeling off or falling down, additional parts can be optionally modified. A cover ring 138 including a body 138b ceramic bead-blasted with a layer 138a thereon is provided on the support unit 142a along a circumference thereof, surrounding the conductive pedestal 134. The body 138b is, for example, quartz. FIG. 3 is a top view of the cover ring 138, showing a ceramic bead-blasted top surface thereof. Moreover, sidewalls of the support unit 142 are also ceramic bead-blasted, shown as a layer 146 illustrated in FIG. 1. The described ceramic bead-blasted layers or portions formed on the dome unit 104, the cover ring 138 and the support unit 138 improve adhesion of sputtered by-products from materials of a patterned interconnect and reduces possibility of peeling off or falling down thereof.

Moreover, portions of the upper shield 132 and the lower shield 140 can optionally be ceramic coated, such as regions A and B illustrated in FIG. 1. The ceramic coating formed over the regions A and B may have a thickness of about 5-30 μm. Therefore, surface roughness at those regions can be reduced to less than 45 μm. This is helpful for reducing or preventing particles of by product peeling off or falling down.

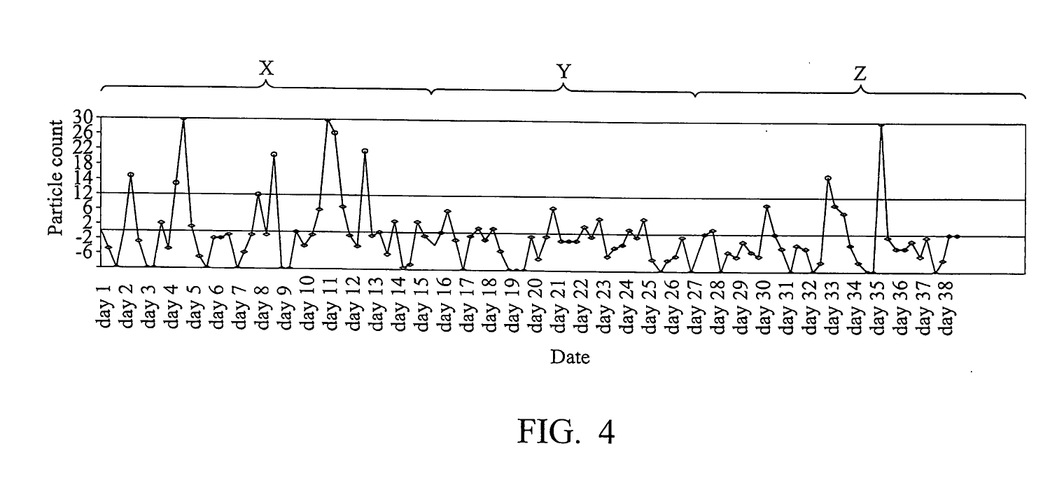

FIG. 4 is a daily particle chart showing particle monitor results of a pre-cleaning tool similar to that illustrated in FIG. I using or not using the disclosed ceramic bead-blasted parts and/or ceramic coating parts. As shown in FIG. 4, with the use of ceramic bead-blasted parts and/or ceramic coating parts, total particle counts can be reduced from 4.72 (period X, without usage ceramic bead-blasted parts and/or ceramic coating parts) to 0.7 (period Y, usage ceramic bead-blasted parts and/or ceramic coating parts), which has 86% reduction, and is increased to 2.5 (period Z, without usage ceramic bead-blasted parts and/or ceramic coating parts). Area count performance is reduced from 1.26 ea (at period X) to 0.35 ea (at period Y), which has 73% reduction.

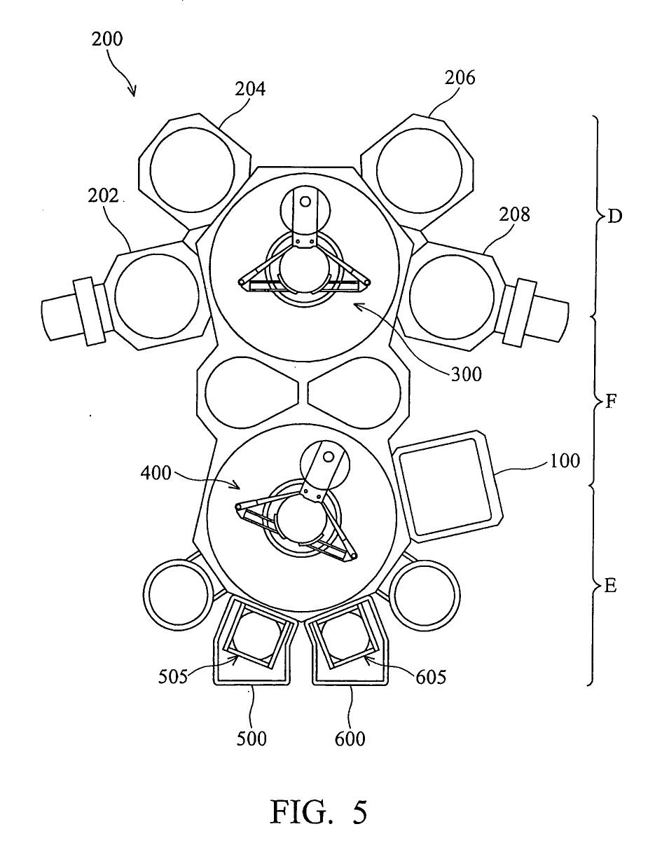

FIG. 5 shows overall layout of a semiconductor process apparatus having a pre-cleaning tool of the invention. As shown in FIG. 5, a schematic top view of a multi-tool processing apparatus 200 suitable for performing, for example CVD, PVD, and plasma treatment process steps of the invention are shown. The apparatus 200 shown herein is suitable for processing planar substrates, such as semiconductor substrates, and is provided to illustrate the invention, and should not be used to limit the scope of the invention. The apparatus 200 typically includes a pre-clean unit E comprising a plurality of load lock chambers 500 and 600 for storing a substrate or a substrate cassette 505/605, a pre-cleaning tool 100 as illustrated in FIG. 1 and a first robot 400 for transferring a substrate from and between the load lock chamber 500/600 and the pre-cleaning tool 100. The apparatus also includes a process unit D comprising a plurality of process chambers 202, 204, 206 and 208 for performing film deposition and a second robot 300 for transferring the substrate from and between the process chambers 202, 204, 206 and 208 and the pre-cleaning tool 100. The process chambers 202, 204, 206, 208 and 100 may function as preclean tools, CVD and PVD deposition tools, and rapid thermal annealing tools and preferably one of the process chambers 202, 204, 206, 208 functions as a PVD or CVD deposition chamber. In addition, a storage unit F is disposed between the process unit D and the pre-clean unit E, wherein the first robot 400 may transfer a substrate from the pre-clean unit E to the storage unit F and the second robot 300 may transfer the substrate from the storage unit F to the process unit D. The first robot 400 may also transfer a substrate from the pre-cleaning tool 100 to the storage unit and the second robot 300 may transfer the substrate from the storage unit F to the load lock chamber 500/600.

While the invention has been described by way of example and in terms of preferred embodiment, it is to be understood that the invention is not limited thereto. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A pre-cleaning tool, comprising:
a support unit for supporting a substrate;
a dome unit for substantially covering the support unit, wherein the dome unit is partially ceramic bead-blasted at an inner surface thereof;
a first RF unit connected to the support unit; and
a second RF unit connected to the dome unit.

2. The pre-cleaning tool as claimed in claim 1, wherein the inner surface of the dome unit is ceramic bead-blasted at a top center portion and a bottom circumference thereof.

3. The pre-cleaning tool as claimed in claim 2, wherein the ceramic bead-blasted center portion of the dome unit is about 10˜18 cm from a center of the dome unit.

4. The pre-cleaning tool as claimed in claim 2, wherein the ceramic bead-blasted bottom circumference of the dome unit is a strip region about 3˜8 cm wide extending from a bottom surface toward the center of the dome unit.

5. The pre-cleaning tool as claimed in claim 2, wherein the dome unit comprises quartz and the dome unit is partially bead-blasted with aluminum oxide, calcium oxide, magnesium oxide, titanium oxide, zirconium oxide, or Teflon®.

6. The pre-cleaning tool as claimed in claim 1, the support unit further comprising:
a pedestal for supporting a substrate;
a support unit for supporting the pedestal; and
a cover ring disposed along a circumference of the support unit.

7. The pre-cleaning tool as claimed in claim 6, wherein the cover ring comprises quartz and a top surface thereof is ceramic bead-blasted.

8. The pre-cleaning tool as claimed in claim 6, wherein the support unit comprises Al and outer sidewalls thereof are ceramic bead-blasted.

9. The pre-cleaning tool as claimed in claim 6, further comprising:
a first shield for supporting the support unit;
a second shield connected to the dome unit for substantially joining with the first shield to thereby provide a process spacing.

10. The pre-cleaning tool as claimed in claim 9, wherein the first and the second shields are partially coated with a ceramic layer to reduce surface roughness thereof to less than 45 cm.

11. The pre-cleaning tool as claimed in claim 10, wherein the ceramic layer has a thickness of about 5-30 μm.

12. A semiconductor manufacturing apparatus, comprising:
a pre-clean unit, comprising:
a load lock chamber for storing a substrate or a substrate cassette;
the pre-cleaning tool of claim 1; and
a first robot for transferring a substrate from and between the load lock chamber and the pre-cleaning tool; and
a process unit, comprising:
a process chamber for performing film deposition; and
a second robot for transferring the substrate from and between the process chamber and the pre-cleaning tool.

13. The semiconductor manufacturing apparatus as claimed in claim 12, wherein the process chamber is a PVD or CVD chamber.

14. The semiconductor manufacturing apparatus as claimed in claim 12, further comprising a storage unit disposed between the process unit and the pre-clean unit, wherein the first robot transfers a substrate from the pre-clean unit to the storage unit and the second robot transfers the substrate from the storage unit to the process chamber.

15. The semiconductor manufacturing apparatus as claimed in claim 14, wherein the second robot transfers a substrate from the pre-cleaning tool to the storage unit and the first robot transfers the substrate from the storage unit to the load lock chamber.
